(19) United States
(12) Patent Application Publication
(10) Pub. No.: US 2026/0260677 A1
(43) Pub. Date: Sep. 3, 2026

(54) PROGRAMMING METHOD FOR THREE-DIMENSIONAL MEMORY

(71) Applicant: CHENGDU PBM TECHNOLOGY LTD., Chengdu (CN)

(72) Inventors: Zezhong PENG, Chengdu (CN); Ke WANG, Chengdu (CN)

(21) Appl. No.: 19/556,783

(22) Filed: Mar. 4, 2026

Related U.S. Application Data
(63) Continuation-in-part of application No. PCT/CN2025/090607, filed on Apr. 23, 2025.

(30) Foreign Application Priority Data
Jun. 28, 2024 (CN) 202410853191.X

(51) Int. Cl. G11C 7/10; G11C 8/10

(52) U.S. Cl. CPC G11C 7/1096; G11C 8/10

(57) ABSTRACT

A programming method for a three-dimensional memory includes: floating at least one of a high-voltage level input line and a low-voltage level input line of an unselected memory cell; and applying a first voltage level VH to a high-voltage level input line of a selected memory cell, and a second voltage level VL to a low-voltage level input line of the selected memory cell, where the first voltage level VH and the second voltage level VL satisfy the following relationship: VH>0 and VL<0, and a sum of an absolute value of the first voltage level VH and an absolute value of the second voltage level VL is equal to a preset programming voltage.

### CROSS-REFERENCE TO RELATED APPLICATION

This patent application is a continuation-in-part of International Patent Application No. PCT/CN2025/090607, filed Apr. 23, 2025, which claims the benefit of and priority to Chinese Patent Application No. 202410853191.X, filed Jun. 28, 2024, each of which is hereby incorporated by reference herein in its entirety.

### TECHNICAL FIELD

The present disclosure relates to integrated circuit technologies, and in particular to three-dimensional memory technologies.

### BACKGROUND

As conventional technology, in the US patent publication US 2013/0043453 A1 (cf. FIG. 1 and FIG. 2) has disclosed that vertical bit lines (BLs) of a 3D memory device are selected by an underlying BL decoder array circuit, and word lines (WLs) in each layer of the multi-layer stacked memory are similarly selected by an underlying WL decoder array circuit. In conventional programming methods for such memories, a positive or negative voltage equal to a programming voltage (Vpp) is typically applied to the WL terminal, and the other terminal (corresponding to BL) is grounded (Gnd). This is because the vertical BLs are densely arranged in a dot-matrix pattern, where the underlying selection transistors are generally not suitable for complex circuit implementations. Therefore, the simplest Metal-Oxide-Semiconductor (mos) Transistor is preferably used for bit line selection. In this case, the BL selection mos transistors can achieve two logic states for voltage input including 0 V and floating (abbreviated as “flt”), corresponding to the selected BL and the unselected BL, respectively.

In order to enable better independent operations of different memory cells in this type of 3D memory, each memory cell is paired with a separate diode rectifier unit, typically a pn-junction diode or a Schottky diode. A rectification direction of the diode depends on conductivity types of the WL and the BL. If the BL selection transistor has only two states—0 V and floating—the WL needs to achieve a positive or negative voltage of absolute value Vpp in the programming state. The programming voltages for this 3D memory are shown in Table 1.

TABLE 1

| | Cell | V (WL) | V (BL) |
|---|---|---|---|
| Programming | Aa SW/SB | Vpp | 0 V |
| | Ab SW/UB | Vpp | Floating |
| | Ba UW/SB | Floating | 0 V |
| | Bb UW/UB | Floating | Floating |

When the Vpp voltage is high, the power consumption and leakage current of the drive circuit also increase significantly. In particular, in order to further enhance the performance of a high-capacity and high-density memory device, horizontal electrodes are best made from metal materials with extremely low resistivity that can form part of the Schottky diode, while metal materials with mature processing techniques, which are suitable for vertical etching with a high aspect ratio, such as aluminum and titanium, are generally n-type conductive materials. This means that if the BL selection transistor has only two states—0 V and floating—the WL selection transistor needs to achieve a negative voltage of absolute value Vpp. Negative-voltage drive circuits tend to be more power-consuming and exhibit higher leakage currents.

FIG. 3 shows another circuit structure of the conventional technology, and Table 2 lists its programming operation voltages (Vpp=6V, and Vdd=2V).

TABLE 2

| | Cell | V (WL) | V (BL) | V(rs) | V(cs) |
|---|---|---|---|---|---|
| Programming | Aa SW/SB | Vpp | 0 V | 0 V | Vdd |
| | Ab SW/UB | Vpp | Floating | 0 V | 0 V |
| | | | | Vdd | Vdd/0 V |
| | Ba UW/SB | Floating | 0 V | 0 V | Vdd |
| | Bb UW/UB | Floating | Floating | 0 V | 0 V |
| | | | | Vdd | Vdd/0 V |

flt: Floating;
SW: Selected word line;
UW: Unselected word line;
SB: Selected bit line;
UB: Unselected Bit line;
rs: Row Select;
cs: Column Select.

### SUMMARY

### Technical Problem

The technical problem to be solved by the present disclosure is to provide a programming method for a three-dimensional memory with low leakage current, low power consumption, and high stability.

### Technical Solution

The technical solution adopted by the present disclosure to solve the technical problem is a programming method for a three-dimensional memory. The method includes the following steps:
(1) floating at least one of a high-voltage level input line and a low-voltage level input line of an unselected memory cell; and
(2) applying a first voltage level VH to a high-voltage level input line of a selected memory cell, and a second voltage level VL to a low-voltage level input line of the selected memory cell,
where the first voltage level VH and the second voltage level VL satisfy the following relationship:
VH>0 and VL<0, and a sum of an absolute value of the first voltage level VH and an absolute value of the second voltage level VL is equal to a preset programming voltage.

### Beneficial Effects

The present disclosure still utilizes simple mos transistors to select vertical BLs. Taking advantage of the characteristic that the mos transistors can achieve low voltage output, the programming voltage Vpp is decomposed into Vpw and Vpb applied to WLs and BLs, respectively. A sum of absolute values of the Vpw and Vpb equals the required programming voltage Vpp, where Vpw and Vpb are a negative voltage and a positive voltage, respectively, or vice versa, thereby achieving a voltage difference of Vpp across the two terminals. The method of the present disclosure can reduce the burden on a horizontal WL drive circuit, decrease its overall leakage current and power consumption, and realize a 3D memory with low power consumption and high reliability.

The 3D data memory of the present disclosure uses the simplest mos transistors as the selection transistors to adapt to the vertical BLs densely arranged in a dot-matrix pattern, thereby ensuring the high-density characteristic of the 3D memory. The horizontal wires can use more process-mature metal materials with low electrical conductivity, ensuring the high-capacity and low-cost characteristics of the 3D memory. Furthermore, in this architecture, even if the metal material of the WL is an N-type Schottky conductor that requires a negative-voltage drive circuit, a voltage output value of the negative-voltage drive voltage can be appropriately reduced by decomposing the relatively high programming voltage, thereby ensuring the low power consumption and high reliability characteristics of the 3D memory.

### BRIEF DESCRIPTION OF THE DRAWINGS

FIG. 1 shows a schematic diagram of a structure in the conventional technology;

FIG. 2 shows a diagram of a first circuit module in the conventional technology;

FIG. 3 shows a diagram of a second circuit module in the conventional technology;

FIG. 4 shows a diagram of a circuit module of Example 1;

FIG. 5 shows a diagram of a circuit module of Example 2;

FIG. 6 shows a diagram of a circuit module of Example 3; and

FIG. 7 shows a diagram of a circuit module of Example 4.

### DETAILED DESCRIPTION OF THE EMBODIMENTS

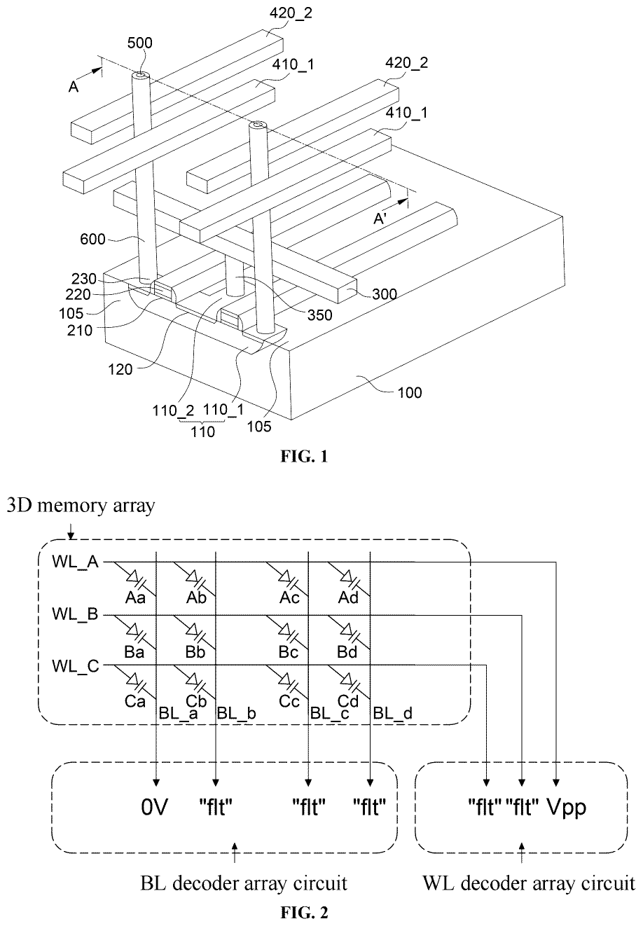

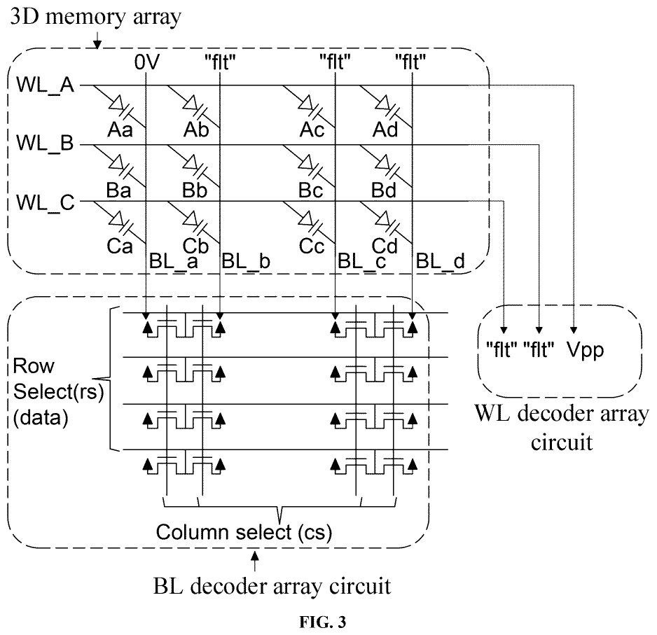

FIG. 1-FIG. 3 provide examples of the prior art. FIG. 1 is a schematic perspective view illustrating a conventional three-dimensional (3D) memory device structure according to the prior art, such as that disclosed in U.S. Patent Publication US 2013/0043453 A1. As shown in FIG. 1, a plurality of vertical bit lines (BLs) extend through a stack of multiple memory layers formed above a substrate. Horizontal word lines (WLs) are arranged in each memory layer and intersect the vertical BLs to define a plurality of memory cells. Bit line selection devices and word line selection devices are disposed beneath the memory array for selecting respective BLs and WLs during memory operations. FIG. 2 is a schematic circuit diagram illustrating a first conventional circuit module for programming operations in a 3D memory device. In FIG. 2, vertical bit lines (BLs) are selectively coupled to ground or left floating by underlying bit line selection transistors, while horizontal word lines (WLs) are selectively driven by a word line decoder circuit. Each memory cell is coupled with a diode rectifying element. The diagram illustrates voltage conditions applied to selected and unselected memory cells during a programming operation, including word line voltages and bit line states of ground or floating. FIG. 3 is a schematic circuit diagram illustrating another conventional circuit structure for a 3D memory device. As shown in FIG. 3, the circuit includes row select (rs) lines and column select (cs) lines for controlling access to the memory array. Programming voltages are applied through combinations of word line voltages, bit line voltages, and row and column selection signals. The figure illustrates representative voltage levels applied during programming operations, including a programming voltage (Vpp), a supply voltage (Vdd), and floating states for unselected lines.

### Example 1

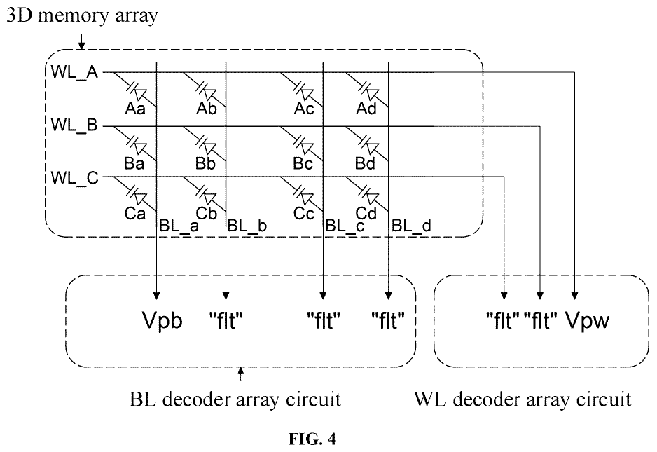

Referring to FIG. 4, a three-dimensional (3D) memory array is provided according to this present disclosure. This memory array includes multiple horizontal word lines WL_A, WL_B, WL_C, and multiple vertical bit lines BL_a, BL_b, BL_c, BL_d. A memory cell, such as Aa, Ab, Ac, Ad, Ba, Bb, Bc, Bd, Ca, Cb, Cc, Cd, is arranged at the intersection between each word line and each bit line. Each memory cell is provided with a diode with a rectification direction oriented from the vertical bit line BL to the horizontal word line WL. The vertical bit lines are selected, through a bit line selection circuit, between the programming voltage Vpb and the floating state (flt). The horizontal word lines are selected, through a word line drive circuit, between the programming voltage Vpw and the floating state (flt). The dashed-line boxes in this figure indicates the bit line selection region and the word line drive region, respectively, where Vpb represents a positive voltage applied to the selected bit line, Vpw represents a negative voltage applied to the selected word line, and flt represents that the corresponding bit line or word line is floated. For example, when Vpp=6V, the value of Vpb can usually range from 2.5 V to 0.9 V depending on the specifications of the mos bit line selection transistor, and thus Vpw ranges from −3.5 V to −5.1 V. Table 3 is a write operation voltage table of this example, and lists the cases where Vpw and Vpb are −4 V and 2 V, respectively. In this case, Vpw changes from the original −6 V to −4 V, thereby reducing the output voltage value of the WL drive circuit.

TABLE 3

| | Cell | V (WL) | V (BL) |
|---|---|---|---|
| Programming | Aa SW/SB | Vpw | Vpb |
| | Ab SW/UB | Vpw | Floating |
| | Ba UW/SB | Floating | Vpb |
| | Bb UW/UB | Floating | Floating |

### Example 2

Referring to FIG. 5, a 3D memory array similar to that shown in FIG. 4 is provided. Unlike Example 1, the rectification direction of the diode is from the horizontal word line WL to the vertical bit line BL. The bit line BL is selectively connected to the programming voltage Vpb or the floating state through the bit line selection circuit, and the word line WL is selectively connected to the programming voltage Vpw or the floating state through the word line drive circuit. In this example, Vpb represents a negative voltage applied to the selected bit line, Vpw represents a positive voltage applied to the selected word line, and a sum of an absolute value of Vpb and an absolute value of Vpw is equal to a preset programming voltage Vpp. For example, when Vpp=6 V, the value of Vpb can usually range from −2.5 V to −0.9 V depending on the specifications of the mos bit line selection transistor, and thus Vpw ranges from 3.5 V to 5.1 V.

Table 4 lists the cases where Vpw and Vpb are 4 V and −2 V, respectively. In this case, Vpw changes from the original 6 V to 4 V, thereby reducing the output voltage value of the WL drive circuit.

TABLE 4

| | Cell | V (WL) | V (BL) |
|---|---|---|---|
| Programming | Aa SW/SB | Vpw | Vpb |
| | Ab SW/UB | Vpw | Floating |
| | Ba UW/SB | Floating | Vpb |
| | Bb UW/UB | Floating | Floating |

### Example 3

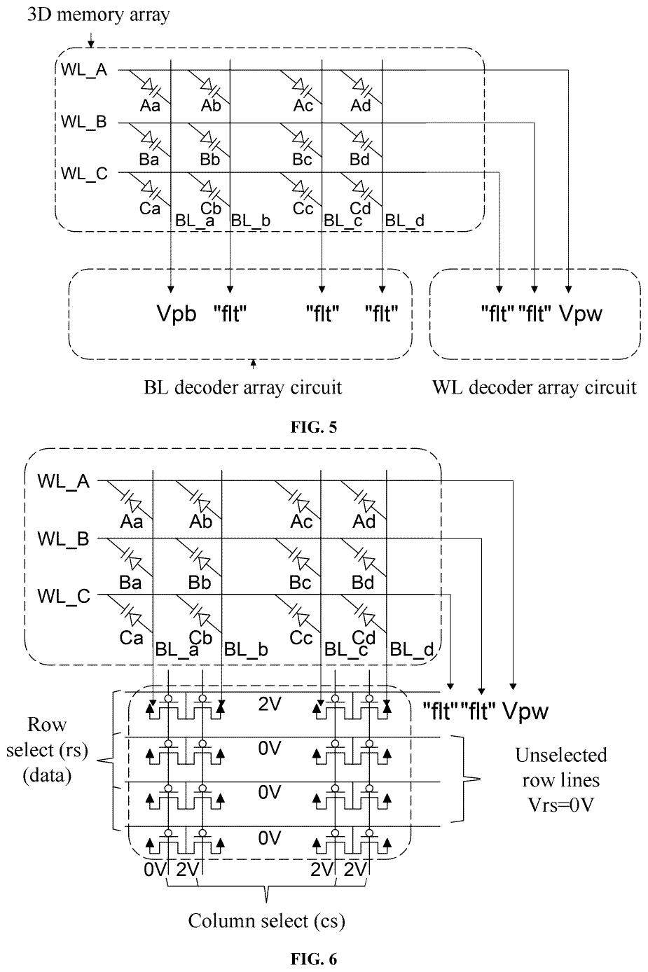

Referring to FIG. 6, a BL decoder array circuit is arranged between the bit lines and the memory array. The BL decoder array circuit includes multiple P-channel mos (pmos) transistors. All pmos transistors of the BL decoder array circuit share a common N-type well (N-well). During operation, the N-well is connected to a high voltage level Vdd (2V).

Through a row select signal, a high voltage level of 2 Vis applied to a selected row line, and a voltage level of 0 V is applied to an unselected row line. Through a column select signal, the corresponding bit line is selected or isolated. The bit line BL connects to the programming voltage or reference voltage when selected, and remains floating when unselected.

Table 5 lists the programming operation voltages (Vpw=−4 V, and Vdd=2 V).

TABLE 5

| | Cell | V_{block} | V (WL) | V (BL) | V(rs) | V(cs) |
|---|---|---|---|---|---|---|
| Programming | Aa SW/SB | 0 V | −4 V | 2 V | 2 V | 0 V |
| | Ab SW/UB | | −4 V | Floating | 2 V | 2 V |
| | | | | | 0 V | 0 V/2 V |
| | Ba UW/SB | | Floating | 2 V | 2 V | 0 V |
| | Bb UW/UB | | Floating | Floating | 2 V | 2 V |
| | | | | | 0 V | 0 V/2 V |

In this example, the vertical BL serves as the anode of the diode, and the horizontal WL serves as the cathode of the diode. Therefore, n-type Schottky metals with high vertical etchability, such as titanium and aluminum, can be used as the horizontal electrode WL, greatly reducing the resistance of the horizontal electrode, facilitating high storage capacity. Additionally, simple-structured pmos transistors are used as the decoder array units for the vertical BLs of the 3D memory array, thereby ensuring high-density integration of the memory.

### Example 4

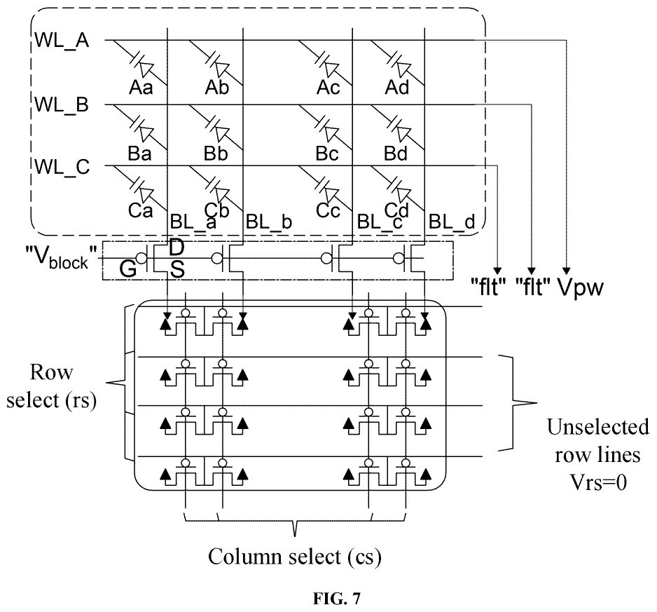

Referring to FIG. 7, on the basis of Example 2, to prevent the breakdown of the gate insulating layer of the BL selection transistor caused by the BL potential being pulled high when the storage medium changes from a high-resistance state to a low-resistance state, a high-voltage blocking component composed of vertical pmos transistors is inserted between the vertical BLs and the selection transistors, as shown in the dashed box in FIG. 7. To ensure the effective operation of the high-voltage blocking component, its mos channel needs to remain in a normally-on state, which is regulated by the gate turn-on voltage Vblock (e.g., 0 V). Additionally, the thickness of its gate insulating layer needs to be sufficient to prevent breakdown. By installing the high-voltage blocking component, the memory array can be effectively isolated from the bit line selection transistors, preventing excessive voltage transmission caused by changes in the resistance state of the memory cells. Compared to Example 3, this example offers higher reliability without compromising any operational performance.

What is claimed is:

1. A programming method for a three-dimensional memory comprising the following steps:
(1) floating at least one of a high-voltage level input line and a low-voltage level input line of an unselected memory cell; and
(2) applying a first voltage level VH to a high-voltage level input line of a selected memory cell, and a second voltage level VL to a low-voltage level input line of the selected memory cell,
wherein the first voltage level VH and the second voltage level VL satisfy the following relationship:
VH>0 and VL<0, and a sum of an absolute value of the first voltage level VH and an absolute value of the second voltage level VL is equal to a preset programming voltage.

2. The programming method for the three-dimensional memory according to claim 1, wherein the first voltage level VH is greater than 1 V, and the second voltage level VL is less than −1 V.
